(19) United States
(12) Patent Application Publication
(10) Pub. No.: US 2023/0155603 A1
(43) Pub. Date: May 18, 2023

(54) AD CONVERTER

(71) Applicant: Rohm Co., Ltd., Kyoto (JP)

(72) Inventors: Koji SAITO, Kyoto (JP); Ryoichi KUROKAWA, Kyoto (JP)

(21) Appl. No.: 17/986,362

(22) Filed: Nov. 14, 2022

(30) Foreign Application Priority Data
Nov. 16, 2021 (JP) 2021186399

(51) Int. Cl. H03M 1/46; H03M 1/12

(52) U.S. Cl. CPC H03M 1/468; H03M 1/1255

(57) ABSTRACT

An AD converter includes: a DA converter; a comparator configured to be capable of resetting a comparison output signal to a first level after a comparison operation is performed based on an output of the DA converter and before a next comparison operation is performed; a level shifter configured to be capable of level-shifting and outputting the comparison output signal such that a change from the first level to a second level is faster than a change from the second level to the first level; a register configured to be capable of obtaining the output of the level shifter; and a logic circuit configured to be capable of controlling the DA converter.

### CROSS-REFERENCE TO RELATED APPLICATION

This application is based upon and claims the benefit of priority from Japanese Patent Application No. 2021-186399, filed on Nov. 16, 2021, the entire contents of which are incorporated herein by reference.

### TECHNICAL FIELD

The present disclosure relates to an AD converter.

### BACKGROUND

In the related art, an ADC (AD converter) that converts an analog signal to a digital signal has been applied to various systems. As a type of ADC, there is a successive approximation ADC.

In the successive approximation ADC, a conversion operation by successive approximation is performed for each number of bits corresponding to the number of conversion bits (for example, 16 bits) for AD conversion. In the AD conversion sequence, the conversion operation for the number of conversion bits occupies most of a period of the sequence. Therefore, a faster operation may be realized by shortening a conversion operation time per bit.

### SUMMARY

Some embodiments of the present disclosure provide a successive approximation AD converter capable of realizing a high-speed operation.

According to an embodiment of the present disclosure, an AD converter includes: a DA converter; a comparator configured to be capable of resetting a comparison output signal to a first level after a comparison operation is performed based on an output of the DA converter and before a next comparison operation is performed; a level shifter configured to be capable of level-shifting and outputting the comparison output signal such that a change from the first level to a second level is faster than a change from the second level to the first level; a register configured to be capable of obtaining the output of the level shifter; and a logic circuit configured to be capable of controlling the DA converter.

### BRIEF DESCRIPTION OF DRAWINGS

The accompanying drawings, which are incorporated in and constitute a part of the specification, illustrate embodiments of the present disclosure.

FIG. 1 is a schematic diagram showing a structure of an AD converter (ADC) according to a comparative example.

FIG. 2 is a diagram more specifically showing a portion of the structure shown in FIG. 1.

FIG. 3 is a diagram showing an example of an AD conversion sequence in the ADC.

FIG. 4 is a timing chart showing an example of a conversion operation by which n-th bit data in the structure shown in FIG. 2 is determined.

FIG. 5 is a diagram showing a structure example of a latch type comparator.

FIG. 6 is a schematic diagram showing a structure of an ADC according to an embodiment of the present disclosure.

FIG. 7 is a diagram more specifically showing a portion of the structure shown in FIG. 6.

FIG. 8 is a timing chart showing an example of a conversion operation by which n-th bit data in the structure shown in FIG. 7 is determined.

FIG. 9 is a diagram showing a first structure example of a latch type comparator.

FIG. 10 is a diagram showing a second structure example of a latch type comparator.

FIG. 11 is a diagram showing a structure of a level shifter according to a first embodiment of the present disclosure.

FIG. 12 is a timing chart showing an operation example of the level shifter according to the first embodiment.

FIG. 13 is a diagram showing a structure of a level shifter according to a second embodiment of the present disclosure.

FIG. 14 is a diagram showing a configuration of a level shifter according to a third embodiment of the present disclosure.

FIG. 15 is a diagram showing a structure of a level shifter according to a fourth embodiment of the present disclosure.

FIG. 16 is a timing chart showing an example of an operation during sampling/holding.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Exemplary embodiments of the present disclosure will be described below with reference to the drawings.

<1. Embodiment according to Comparative Example>

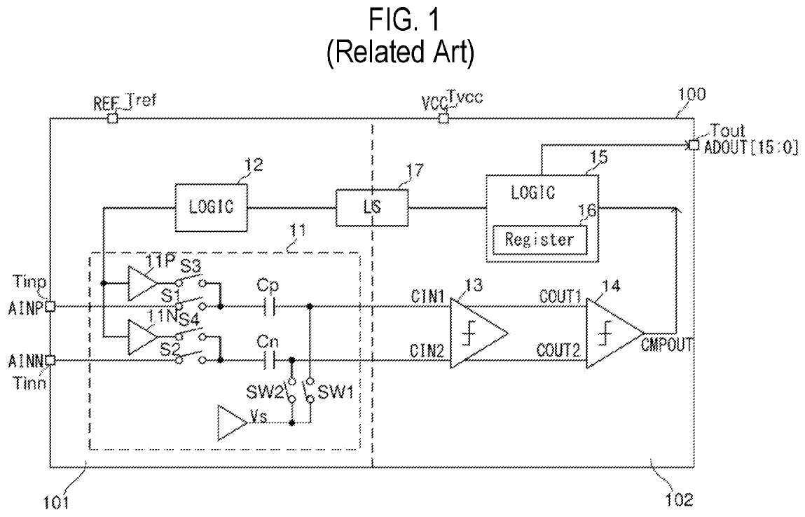

Prior to describing the embodiments of the present disclosure, a comparative example for comparison with the present disclosure will be described. FIG. 1 is a schematic diagram showing a structure of an AD converter (analog digital converter; hereinafter referred to as ADC) 100 according to a comparative example.

The ADC 100 shown in FIG. 1 includes a DA converter (digital analog converter; hereinafter, referred to as DAC) 11, a logic circuit 12, a comparator 13, a latch type comparator 14, a logic circuit 15, and a level shifter 17. The logic circuit 15 includes a register 16. The ADC 100 includes a reference voltage terminal Tref, a power supply terminal Tvcc, an AD output terminal Tout, and AD input terminals Tinp and Tinn.

The ADC 100 is a differential input type ADC that AD-converts a voltage difference between analog input signals AINP (positive side) and AINN (negative side) inputted to the input terminals Tinp and Tinn, respectively, and outputs a digital output signal ADOUT from an output terminal Tout. However, the ADCs according to the comparative example and the embodiments of the present disclosure described later are not limited to differential input types, and may be single end input types. In the following description, the ADC 100 performs AD conversion with the number of conversion bits, which is, for example, 16 bits. That is, a 16-bit digital output signal ADOUT is outputted. The number of conversion bits may be a number of bits (e.g., 12 bits) other than 16 bits.

The ADC 100 includes a first block 101 operating with a reference voltage REF applied to a reference voltage terminal Tref, and a second block 102 operating with a power supply voltage VCC applied to a power supply terminal Tvcc. The DAC 11 and the logic circuit 12 are included in the first block 101. The comparator 13, the latch type comparator 14, and the logic circuit 15 are included in the second block 102.

The reference voltage REF serves as a reference voltage of the DAC 11 and determines an input dynamic range of the ADC 100. However, since a measurement voltage range varies depending on a measurement target, the voltage range in which the reference voltage REF may be applied may be widened (e.g., 2.5 to 5V). On the other hand, the power supply voltage VCC is a power supply voltage of the comparator 13 and the latch type comparator 14 for high-speed operation and high accuracy. Therefore, an allowable voltage range of the power supply voltage is narrow (e.g., 3V±10%) to optimize characteristics. The level shifter 17 is provided to convert a signal level between the second block 102 and the first block 101.

The DAC 11 performs a function of sampling/holding, and includes switches S1 to S4, capacitors Cp and Cn, voltage appliers 11P and 11N, and switches SW1 and SW2.

A first end of the capacitor Cp is connected to the AD input terminal Tinp via the switch S1. A first terminal of the capacitor Cn is connected to the AD input terminal Tinn via the switch S2. An output end of the voltage applier 11P is connected to the first end of the capacitor Cp via the switch S3. An output end of the voltage applier 11N is connected to the first terminal of the capacitor Cn via the switch S4.

FIG. 1 illustrates structures of the switches S1 to S4, the capacitors Cp and Cn, and the voltage appliers 11P and 11N, when the number of conversion bits is one bit. In reality, the switches S1 to S4, the capacitors Cp and Cn, and the voltage appliers 11P and 11N are provided for each bit of the number of conversion bits. In this case, a second end of the capacitor Cp provided for each bit is commonly connected to a first input end of the comparator 13, and a second end of the capacitor Cn provided for each bit is commonly connected to a second input end of the comparator 13.

A node to which the second end of the capacitor Cp provided for each bit is commonly connected to an application end of a fixed voltage Vs via the switch SW1. A node to which the second terminal of the capacitor Cn provided for each bit is commonly connected is connected to the application end of the fixed voltage Vs via the switch SW2. The fixed voltage Vs is, for example, 1V.

By turning on the switches S1 and S2 and the switches SW1 and SW2, the capacitors Cp and Cn are charged, and the analog input signals AINP and AINN are sampled and held.

An input signal CIN1 is inputted to the first input end of the comparator 13, and an input signal CIN2 is inputted to the second input end of the comparator 13. The comparator 13 amplifies the voltage difference between the comparison input signals CIN1 and CIN2 and outputs output signals COUT1 and COUT2. The latch type comparator 14 is arranged behind the comparator 13 to compare the output signals COUT1 and COUT2 to output a comparison output signal CMPOUT as a comparison result.

The comparison output signal CMPOUT is obtained and held in the register 16. The logic circuits 15 and 12 control the voltage applier 11P. Specifically, when “1” is set as bit data, the logic circuits 15 and 12 cause the voltage applier 11P to apply a high-level voltage (reference voltage REF) to the first end of the capacitor Cp. When “0” is set as bit data, the logic circuits 15 and 12 cause the voltage applier 11P to apply a low-level voltage (ground potential) to the first end of the capacitor Cp. The voltage applier 11N is controlled to apply a voltage opposite in phase to that of the voltage applier 11P to the first end of the capacitor Cn. However, the present disclosure is not limited thereto. For example, the voltage applier 11N may be controlled to constantly apply a low-level voltage to the first end of the capacitor Cn.

In the AD conversion sequence performed by the ADC 100, first, the DAC 11 samples and holds analog input signals AINP and AINN. With the sampling/holding completed, the switches S1 and S2 and the switches SW1 and SW2 are in an off state. After the sampling/holding, the process proceeds to a successive approximation period.

The switches S3 and S4 are in an on state during the successive approximation period. First, under the control of the logic circuits 15 and 12, “1” is set as the most significant bit (MSB) and “0” is set as other bits. At this time, a high-level voltage is applied to the first end of the capacitor Cp corresponding to the MSB, and a low-level voltage is applied to the first end of the capacitor Cp corresponding to other bits.

At this time, the comparison output signal CMPOUT is outputted from the latch type comparator 14 based on the input signals CIN1 and CIN2 inputted to the comparator 13. The comparison output signal CMPOUT represents a magnitude comparison result between the digital data (16-bit data) in which “1” is set as the MSB and “0” is set as other bits and the voltage difference between the analog input signals AINP and AINN. That is, the comparator 13 and the latch type comparator 14 perform a magnitude comparison between the digital data and the voltage difference between the analog input signals AINP and AINN.

When the digital data is larger than the voltage difference between the analog input signals AINP and AINN, the comparison output signal CMPOUT becomes a high-level signal, the high-level signal is held in the register corresponding to the MSB in the register 16, and the data of the MSB is determined to be “1.” On the other hand, when the digital data is smaller than the voltage difference between the analog input signals AINP and AINN, the comparison output signal CMPOUT becomes a low-level signal, the low-level signal is held in the register corresponding to the MSB in the register 16, and the data of the MSB is determined to be “0.” Thereafter, under the control of the logic circuits 15 and 12, a voltage of a level corresponding to the MSB data is applied to the first end of the capacitor Cp corresponding to the determined MSB.

Then, under the control of the logic circuits 15 and 12, “1” is set as a next bit lower than the MSB, and “0” is set to as bits lower than the next bit. At this time, a high-level voltage is applied to the first end of the capacitor Cp corresponding to the next bit lower than the MSB, and a low-level voltage is applied to the first end of the capacitor Cp corresponding to the bits lower than the next bit.

Then, the magnitude comparison between the digital data, in which the determined data is set as the MSB, “1” is set as the next bit lower than the MSB, and “0” is set as other bits, respectively, and the voltage difference between the analog input signals AINP and AINN is performed by the comparator 13 and the latch type comparator 14. The comparison result represented by the comparison output signal CMPOUT is obtained by the register corresponding to the next bit lower than the MSB in the register 16, and the data of the next bit is determined.

Thereafter, the same operation is performed, and the respective bits are sequentially determined while performing successive approximation until the data of the least significant bit (LSB) is determined. Data (16-bit data) corresponding to the determined conversion bit number is retrieved from the register 16 as a digital output signal ADOUT.

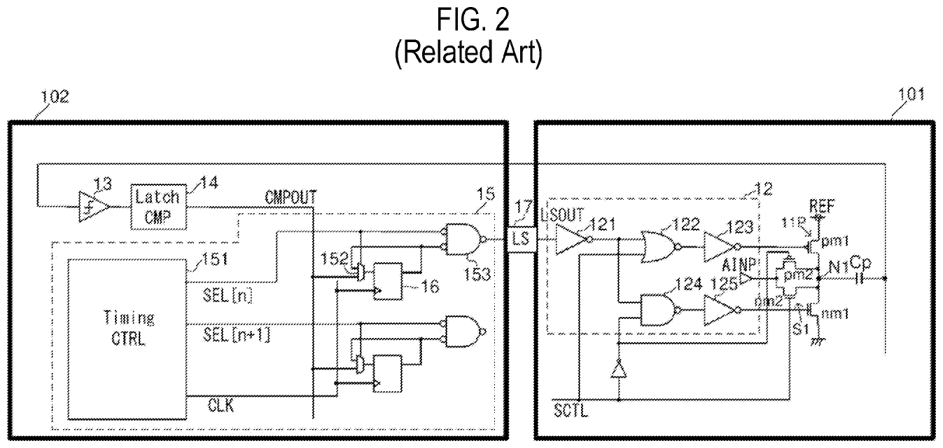

FIG. 2 is a diagram more specifically showing a portion of the structure shown in FIG. 1. As shown in FIG. 2, the logic circuit 15 includes a timing controller 151, a selector 152, a NAND 153, and a register 16.

The timing controller 151 outputs selection signals SEL of the number (16) corresponding to the number of conversion bits. Further, the timing controller 151 also outputs a clock signal CLK.

The selection signal SEL is inputted to a first inverting input terminal of the NAND 153. The comparison output signal CMPOUT outputted from the latch type comparator 14 is inputted to a first input end of the selector 152. The register 16 is constituted as a D flip-flop. An output end of the selector 152 is connected to a D input end of the register 16. A Q output end of the register 16 is connected to a second input end of the selector 152 and a second inverting input end of the NAND 153. The clock signal CLK is inputted to a clock input end of the register 16. The selector 152 selects and outputs a signal inputted to the first input end or the second input end according to the level of the selection signal SEL.

The selector 152, the NAND 153, and the register 16 are provided for each bit of the conversion bit number. FIG. 2 illustrates structures respectively corresponding to selection signals SEL[n], which corresponds to the n-th bit, and SEL[n+1].

Further, as shown in FIG. 2, the logic circuit 12 includes an inverter 121, a NOR 122, an inverter 123, a NAND 124, and an inverter 125.

The output end of the NAND 153 is connected to the input end of the level shifter 17. The output end of the level shifter 17 is connected to the input end of the inverter 121. The output end of the inverter 121 is connected to a first input end of the NOR 122. A switch control signal SCTL is inputted to the second input end of the NOR 122. The output end of the NOR 122 is connected to the input end of the inverter 123. The output end of the inverter 121 is connected to the first input end of the NAND 124. The switch control signal SCTL is level-inverted and inputted to the second input end of the NAND 124. The output end of the NAND 124 is connected to the input end of the inverter 125.

The voltage applier 11P includes a PMOS transistor (P-channel MOSFET (metal-oxide-semiconductor field-effect transistor)) pm1 and an NMOS transistor (N-channel MOSFET) nm1. A source of the PMOS transistor pm1 is connected to the application end of the reference voltage REF. A drain of the PMOS transistor pm1 is connected to a drain of the NMOS transistor nm1. A source of the NMOS transistor nm1 is connected to a ground potential application end. The output end of the inverter 123 is connected to a gate of the PMOS transistor pm1. The output end of the inverter 125 is connected to a gate of the NMOS transistor nm1. A node N1 where the PMOS transistor pm1 and the NMOS transistor nm1 are connected is connected to the first end of the capacitor Cp.

As shown in FIG. 2, the switch S1 includes a PMOS transistor pm2 and an NMOS transistor nm2. The PMOS transistor pm2 and the NMOS transistor nm2 are connected in parallel between the application end of the analog input signal AINP and the node N1. A signal obtained by inverting the level of the switch control signal SCTL is inputted to a gate of the PMOS transistor pm2. The switch control signal SCTL is inputted to a gate of the NMOS transistor nm2.

When the switch control signal SCTL is at a high level, the PMOS transistor pm2 and the NMOS transistor nm2 are in an on state. That is, the switch S1 is in an on state. At this time, the PMOS transistor pm1 and the NMOS transistor nm1 are in an off state. That is, it corresponds to turning off the switch S3 (FIG. 1).

When the switch control signal SCTL is at a low level, the switch S1 is in an off state. At this time, the first input end of the NOR 122 and the first input end of the NAND 124 are enabled, and the on/off states of the PMOS transistor pm1 and the NMOS transistor nm1 are switched according to the signal level inputted to each of the first input ends. When the PMOS transistor pm1 is in an on state and the NMOS transistor nm1 is in an off state, a high-level voltage (reference voltage REF) is applied to the first end of the capacitor Cp. When the PMOS transistor pm1 is in an off state and the NMOS transistor nm1 is in an on state, a low-level voltage (ground potential) is applied to the first end of the capacitor Cp. That is, it corresponds to turning on the switch S3.

The level shifter 17, the logic circuit 12, the voltage applier 11P, the switch S1, and the capacitor CP are provided for each bit of the number of conversion bits. For the sake of convenience, FIG. 2 illustrates the structure corresponding to the selection signal SEL[n].

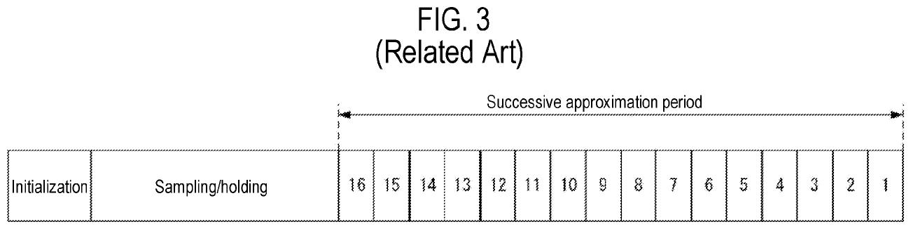

FIG. 3 shows an example of an AD conversion sequence in the ADC. As shown in FIG. 3, in the AD conversion sequence, initialization is performed first, and then sampling/holding is performed. Then, in the successive approximation period, a conversion operation is performed for each bit of the number of conversion bits, and bit data is determined in order from the MSB.

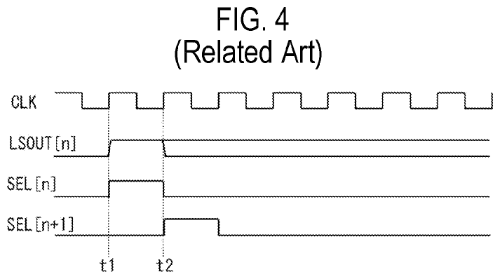

A conversion operation that determines n-th bit data in the structure shown in FIG. 2 will be described with reference to the timing chart shown in FIG. 4. In FIG. 4, the clock signal CLK, the output LSOUT[n] of the level shifter 17 corresponding to the n-th bit, the selection signal SEL[n] corresponding to the n-th bit, and the selection signal SEL[n+1] corresponding to the (n+1)-th bit are shown sequentially from the top. The switch control signal SCTL is at the low level.

First, the selection signal SEL[n] rises in synchronization with the rise of the clock signal CLK (timing t1). Then, the output of the NAND 153 is at a high level, and the selector 152 selects and outputs the comparison output signal CMPOUT outputted from the latch type comparator 14. Thus, as shown in FIG. 4, the output LSOUT[n] of the level shifter 17 rises to a high level, and the outputs of the inverters 123 and 125 go to a low level, whereby the PMOS transistor pm1 is in an on state and the NMOS transistor nm1 is in an off state, such that a high-level voltage is applied to the first end of the capacitor Cp. As a result, “1” is set as the n-th bit data.

At this time, selection signals SEL (SEL[n+1], SEL[n+2], . . . ) corresponding to the n+1-th and subsequent bits are at a low level, and the corresponding Q outputs of the register 16 are also at a low level. Therefore, the output of the NAND 153 is at a low level, the outputs of the inverters 123 and 125 are at a high level, the PMOS transistor pm1 is in an off state, the NMOS transistor nm1 is in an on state, and a low-level voltage is applied to the first end of the capacitor Cp. As a result, “0” is set as the n+1-th and subsequent bit data.

Then, a comparison operation is performed in the latch type comparator 14. The comparison result is held in the latch type comparator 14 until the next comparison operation.

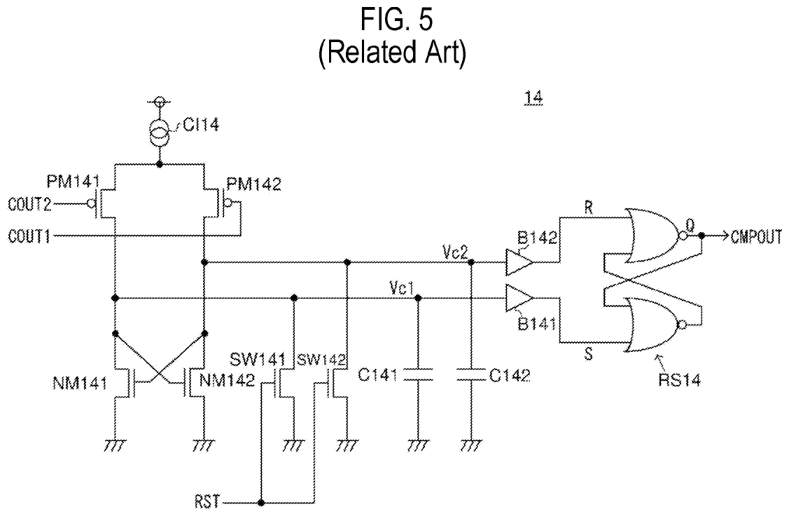

FIG. 5 shows a structure example of the latch type comparator 14. The latch-type comparator 14 includes a constant current source CI14, PMOS transistors PM141 and PM142, NMOS transistors NM141 and NM142, switches SW141 and SW142, capacitors C141 and C142, buffers B141 and B142, and a flip-flop RS14.

The constant current source CI14 is arranged between a power supply voltage application end and a node to which a source of each of the PMOS transistors PM141 and PM142 is connected. A drain of the PMOS transistor PM141 is connected to a drain of the NMOS transistor NM141. A source of the NMOS transistor NM141 is connected to the ground potential application end. A drain of the PMOS transistor PM142 is connected to a drain of the NMOS transistor NM142. A source of the NMOS transistor NM142 is connected to the ground potential application end. A gate of the NMOS transistor NM141 is connected to the drain of the NMOS transistor NM142. A gate of the NMOS transistor NM142 is connected to the drain of the NMOS transistor 141.

The switches SW141 and SW142 include NMOS transistors. The drain of the switch SW141 is connected to the drain of the PMOS transistor PM141. The drain of the switch SW142 is connected to the drain of the PMOS transistor PM142. The sources of the switches SW141 and SW142 are connected to the ground potential application end. A first end of the capacitor C141 is connected to the drain of the PMOS transistor PM141. A first terminal of the capacitor C142 is connected to the drain of the PMOS transistor PM142. Second terminals of the capacitors C141 and C142 are connected to the ground potential application end.

The first end of the capacitor C141 is connected to a set end of the flip-flop RS14 via a buffer B141. The first end of the capacitor C142 is connected to a reset end of the flip-flop RS14 via a buffer B142. A comparison output signal CMPOUT is outputted from a Q output end of the flip-flop RS14.

The output signal COUT1 outputted from the preceding comparator 13 (FIG. 1) is inputted to a gate of the PMOS transistor PM142. The output signal COUT2 outputted from the preceding comparator 13 is inputted to a gate of the PMOS transistor PM141.

A reset signal RST is inputted to gates of the switches SW141 and SW142. The switches SW141 and SW142 are turned on in advance by the high-level reset signal RST, the capacitors C141 and C142 are discharged, and the voltages Vc1 and Vc2 at the first ends of the capacitors C141 and C142 are 0 V (reset state). When the reset signal RST is set to a low level, the switches SW141 and SW142 are turned off, and the comparison operation is started.

Then, the capacitors C141 and C142 are charged by the currents flowing through the PMOS transistors PM141 and PM142, and the voltages Vc1 and Vc2 of the capacitors C141 and C142 rise. For example, when COUT1 >COUT2, the current flowing through the PMOS transistor PM141 is larger than the current flowing through the PMOS transistor PM142, and the voltage Vc1 reaches a Vth (threshold voltage) of the NMOS transistors NM141 and NM142 earlier than the voltage Vc2. As a result, the NMOS transistor NM142 is turned on, the voltage Vc2 is set to 0 V, and the NMOS transistor NM141 is turned off. Thus, the voltage Vc1 is held at a high level, and the voltage Vc2 is held at a low level. As a result, the comparison output signal CMPOUT is set to a high level. Similarly, when COUT1<COUT2, the comparison output signal CMPOUT is set to a low level.

After the comparison operation is completed, even in a case where the capacitors C141 and C142 are discharged by the reset signal RST and Vc1 and Vc2 are 0 V, the comparison output signal CMPOUT is held. Then, the comparison output signal CMPOUT is outputted during the next comparison operation.

Returning to FIG. 4, when the clock signal CLK rises again (timing t2), the comparison output signal CMPOUT is obtained by the register 16 corresponding to the n-th bit and outputted from the Q output end. When the clock signal CLK rises, the selection signal SEL[n] falls and the selector 152 selects the Q output of the register 16. Then, since the selection signal SEL[n] continues to fall, the Q output of the register 16 is maintained. As a result, the n-th bit data is determined. In addition, the selection signal SEL[n] is maintained at a low level, and the input of the Q output of the register 16 becomes valid in the NAND 153. Therefore, a voltage is applied to the first end of the capacitor Cp according to the level of the Q output.

At this time, as shown in FIG. 4, at timing t1, the output LSOUT[n] of the level shifter 17 temporarily rises to a high level. Therefore, at timing t2, the output LSOUT[n] is maintained at the high level or falls to a low level depending on the level of the obtained comparison output signal CMPOUT.

When the clock signal CLK rises again (timing t2), the selection signal [n+1] rises. By repeating the same operation, the n+1-th and subsequent bit data are sequentially determined.

As described above, in the structure of this comparative example, both the rise and fall of the output LSOUT of the level shifter 17 may be speeded up. However, it is currently difficult to form such a level shifter. In addition, the selector 152 may be a delay element. This hinders shortening a conversion operation time for each bit.

### <2. Embodiments of the Present Disclosure>

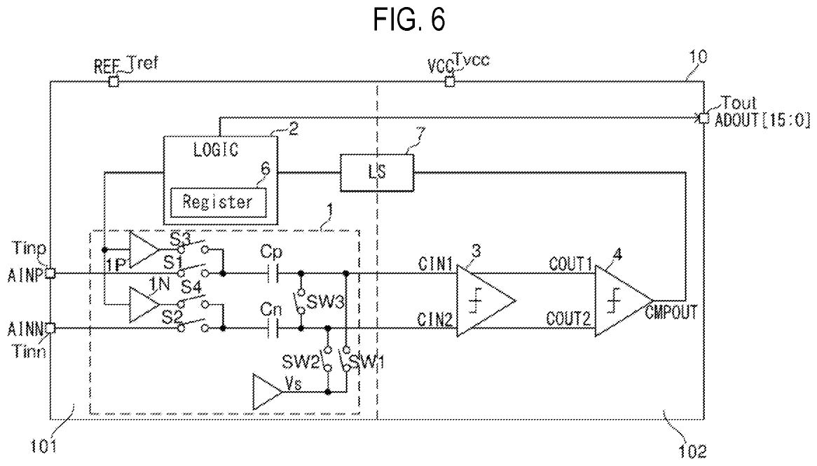

Next, embodiments of the present disclosure will be described. FIG. 6 is a schematic diagram showing a structure of an ADC 10 according to embodiments of the present disclosure. FIG. 6 is a diagram to be compared with FIG. 1 showing the above-described comparative example.

As shown in FIG. 6, the ADC 10 according to the present disclosure includes a DAC 1, a logic circuit 2, a comparator 3, a latch type comparator 4, and a level shifter 7. Further, in the embodiments of the present disclosure, as in the comparative example, the ADC 1 includes a first block 101 which operates with a reference voltage REF applied to a reference voltage terminal Tref and a second block 102 which operates with a power supply voltage VCC applied to a power supply terminal Tvcc. The DAC 1 and the logic circuit 2 are included in the first block 101. The comparator 3 and the latch type comparator 4 are included in the second block 102.

The DAC 1 performs the same sampling/holding function as the DAC 11 according to the comparative example. However, unlike the DAC 11, the DAC 1 includes a switch SW3 related to sampling/holding. Details of the switch SW3 will be described later.

The structure of the comparator 3 is the same as that of the comparator 13 according to the comparative example. The latch type comparator 4 differs in structure from the comparator 14 according to the comparative example, and the details thereof will be described later.

The level shifter 7 is arranged behind the latch type comparator 4 and in front of the logic circuit 2. Details of the level shifter 7 will be described later.

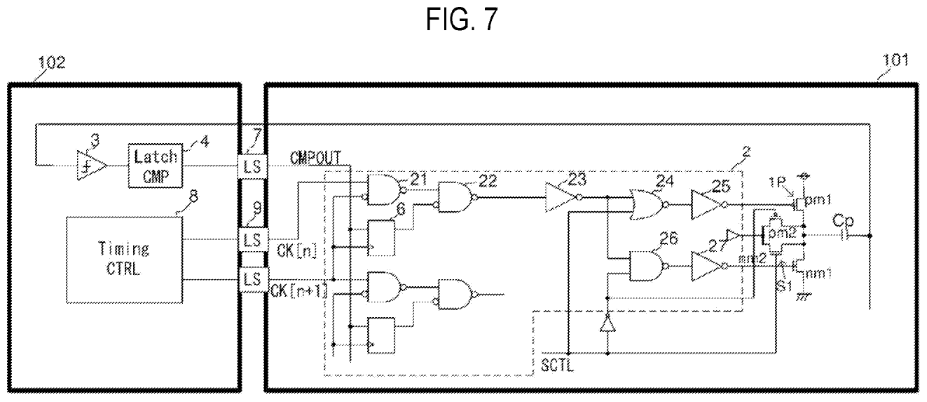

The logic circuit 2 controls the DAC 1 and includes a register 6. The register 6 holds a comparison result (comparison output signal CMPOUT) obtained by the latch type comparator 4. Although not shown in FIG. 6, the ADC 10 further includes a timing controller 8 (see FIG. 7 described later) included in the second block 102. The timing controller 8 controls the logic circuit 2.

FIG. 7 is a diagram more specifically showing a portion of the structure shown in FIG. 6. As shown in FIG. 7, the logic circuit 2 includes NANDs 21 and 22 and a register 6.

The timing controller 8 outputs clock signals CK whose number corresponds to the number of conversion bits (16)+1. FIG. 7 shows the clock signal CK[n] corresponding to the n-th bit and the clock signal CK[n+1] corresponding to the n+1-th bit.

The clock signal CK[n] is inputted to the input end of the NAND 21 via a level shifter 9[n]. The clock signal CK[n+1] is inputted to an inverting input end of the NAND 21 via a level shifter 9[n+1]. The output end of the NAND 21 is connected to the input end of the NAND 22. The register 6 includes a D flip-flop. The comparison output signal CMPOUT outputted from the latch type comparator 4 via the level shifter 7 is inputted to the D input end of the register 6. The clock signal CK[n+1] is inputted to the clock input end of the register 6. The Q output end of the register 6 is connected to the inverting input end of the NAND 22.

The NANDs 21 and 22 and the register 6 are provided for each bit of the number of conversion bits. For the sake of convenience, FIG. 7 illustrates structures respectively corresponding to the clock signals CK[n] and CK[n+1].

As shown in FIG. 7, the logic circuit 2 includes an inverter 23, a NOR 24, an inverter 25, a NAND 26, and an inverter 27. Structures of these components in the logic circuit 2, a voltage applier 1P, a switch S1, and a capacitor Cp are the same as those of the logic circuit 12, the voltage applier 11P, the switch S1, and the capacitor Cp according to the comparative example. The input terminal of the inverter 23 is connected to the output end of the NAND 22.

The inverter 23, the NOR 24, the inverter 25, the NAND 26, the inverter 27, the voltage applier 1P, the switch S1, and the capacitor CP are provided for each bit of the number of conversion bits. For the sake of convenience, FIG. 7 illustrates a configuration corresponding to the clock signal CK[n].

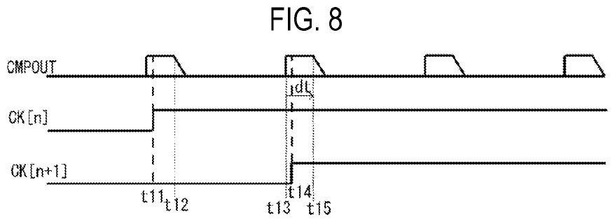

A conversion operation that determines the n-th bit data in the structure shown in FIG. 7 will be described with reference to a timing chart shown in FIG. 8. In FIG. 8, the comparison output signal CMPOUT, the clock signal CK[n], and the clock signal CK[n+1], which are outputted from the level shifter 7, are shown sequentially from the top. The switch control signal SCTL is at the low level.

First, the clock signal CK[n] rises (timing t11). At this time, the clock signal CK[n+1] is at a low level. Thus, the output of the NAND 21 is at a low level, the output of the NAND 22 is at a high level, the PMOS transistor in the switch 1P is turned on, the NMOS transistor is turned off, and a high-level voltage is applied to the first end of the capacitor Cp. As a result, “1” is set as the n-th bit data.

At this time, the n+1-th and subsequent bit clock signals CK (CK[n+1], CK[n+2], . . . ) are at the low level, and the corresponding Q outputs of the register 16 are also respectively at the low level. Therefore, the output of the NAND 22 is at a low level, the PMOS transistor in the switch 1P is turned off, the NMOS transistor in the switch 1P is turned on, and a low-level voltage is applied to the first end of the capacitor Cp. As a result, “0” is set as the n+1-th and subsequent bit data.

Then, at timing t13, the latch type comparator 4 performs a comparison operation. However, the latch type comparator 4 is reset at timing t12, and the comparison output signal CMPOUT is reset to the low level in advance.

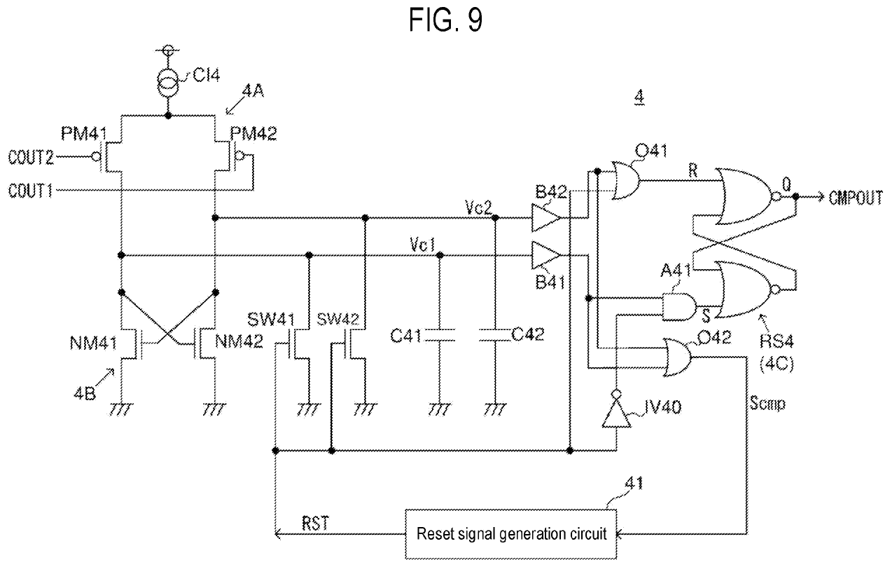

FIG. 9 shows a first structure example of the latch type comparator 4. The latch type comparator 4 shown in FIG. 9 includes a constant current source CI4, PMOS transistors PM41 and PM42, NMOS transistors NM41 and NM42, switches SW41 and SW42, capacitors C41 and C42, buffers B41 and B42, and a flip-flop RS4. Structures of these components are the same as those of the latch-type comparator 14 (FIG. 5) according to the above-described comparative example. The latch-type comparator 4 further includes OR circuits O41 and O42, an AND circuit A41, an inverter IV40, and a reset signal generation circuit 41, which are different in structure from those in the comparative example. The reset signal generation circuit 41 generates a reset signal RST. The reset signal RST is inputted to the gates of the switches SW41 and SW42.

The PMOS transistors PM41 and PM42 and the constant current source CI4 constitute a charger 4A that charges the capacitors C41 and C42 by causing a current to flow therethrough. The NMOS transistors NM41 and NM42 constitute a holder 4B that holds (latches) the voltage levels of the capacitors C41 and C42. The flip-flop RS4 constitutes an output 4C that outputs a comparison output signal CMPOUT.

The output end of the buffer B42 is connected to the first input end of the OR circuit O41. A reset signal RST is inputted to the second input terminal of the OR circuit O41. The output end of the OR circuit O41 is connected to the reset end of the flip-flop RS4. The output end of the buffer B41 is connected to the first input end of the AND circuit A41. A signal obtained by inverting the level of the reset signal RST by the inverter IV40 is inputted to the second input terminal of the AND circuit A41. The output end of the AND circuit A41 is connected to the set end of the flip-flop RS4. The output end of the buffer B42 is connected to the first input end of the OR circuit O42. The output end of the buffer B41 is connected to the second input end of the OR circuit O42. A comparison completion signal Scmp outputted from the OR circuit O42 is inputted to the reset signal generation circuit 41.

By setting the reset signal RST to a high level, the switches SW41 and SW42 are turned on, the capacitors C41 and C42 are discharged, and the voltage Vc1 at the first end of the capacitor C41 and the voltage Vc2 at the first end of the capacitor C42 are set to 0 V (reset). At this time, the output of the OR circuit O41 is at a high level and the output of the AND circuit A41 is at a low level by the reset signal RST, the flip-flop RS4 is reset, and the comparison output signal CMPOUT outputted from the Q output end of the flip-flop RS4 is reset to the low level.

Then, when the reset signal RST is switched to the low level, the switches SW41 and SW42 are turned off, and the comparison operation is started. The output signal COUT1 outputted from the comparator 3 (FIG. 6) is inputted to the gate of the PMOS transistor PM42, and the output signal COUT2 outputted from the comparator 3 is inputted to the gate of the PMOS transistor PM41. For example, when COUT1>COUT2, the voltage Vc1 at the first end of the capacitor C41 is held at the high level and the voltage Vc2 at the first end of the capacitor C42 is held at the low level, as in the comparative example described above. Then, the output of the AND circuit A41 is at a high level, the output of the OR circuit O41 is at a low level, the flip-flop RS4 is set, and the comparison output signal CMPOUT is at a high level. On the other hand, when COUT1<COUT2, the flip-flop RS4 is reset and the comparison output signal CMPOUT is at a low level.

The comparison completion signal Scmp, which is the output of the OR circuit O42, is set to a high level, which indicates the completion of comparison at the timing at which either of the voltages Vc1 and Vc2 is at a high level. The reset signal generation circuit 41 switches the reset signal RST to a high level after a predetermined delay time has elapsed after the comparison completion signal Scmp is at a high level. As a result, the comparison output signal CMPOUT is reset to the low level.

Returning to FIG. 8, the comparison operation is performed in the latch type comparator 4 at timing t13, and the comparison output signal CMPOUT is at a high level or a low level depending on a magnitude relationship between the output signals COUT1 and COUT2. Then, at timing t14, the clock signal CK[n+1] rises to a high level, and the register 6 obtains the comparison output signal CMPOUT. Thereafter, since the clock signal CK[n+1] is maintained at the high level, the level obtained by the register 6 is maintained, and the n-th bit data is determined. At this time, the output of the NAND 21 is at a high level, the voltage applier 1P is controlled according to the level obtained by the register 6, and a high-level voltage or a low-level voltage is applied to the first end of the capacitor Cp.

After timing t14, at timing t15, the latch type comparator 4 is reset, and the comparison output signal CMPOUT is reset to the low level. In the above-described latch type comparator 4 (FIG. 9), the reset signal generation circuit 41 performs the reset operation at timing t15 which is delayed by a delay time dt from the comparison completion timing t13. The delay time dt is set such that a holding time may be secured from timing t14 for the obtaining by the register 6.

When the clock signal CK[n+1] rises to the high level at timing t14, the output of the NAND 21 corresponding to the n+1-th bit is set to a low level, and a high-level voltage is applied to the first end of the corresponding capacitor Cp. That is, “1” is set as the n+1-th bit data. Thereafter, while performing the comparison operation by the latch type comparator 4, the (n+1)-th and subsequent bit data are sequentially determined.

As described above, in the embodiments of the present disclosure, after the comparison operation, the comparison output signal CMPOUT is reset to the low level before the next comparison operation is started in the latch type comparator 4. As a result, the level shifter 7 may speed up the rise from the low level to the high level (e.g., timing t13). Such a level shifter 7 may be realized in various forms as described later. Therefore, it is possible to shorten the conversion operation time per bit.

### <3. Modification of Latch Type Comparator>

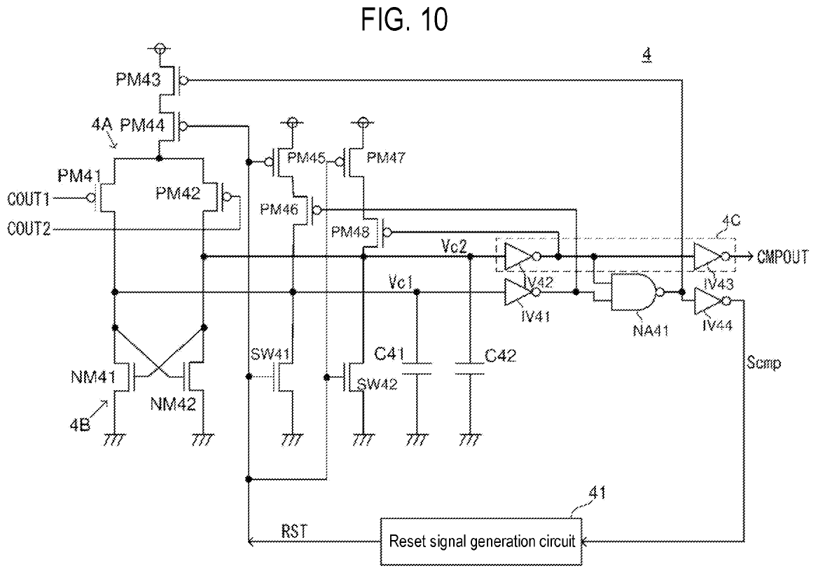

FIG. 10 is a diagram showing a second configuration example of the latch-type comparator 4. Similar to the above-described structure shown in FIG. 9, the latch type comparator 4 shown in FIG. 10 includes PMOS transistors PM41 and PM42, NMOS transistors NM41 and NM42, switches SW41 and SW42, capacitors C41 and C42, and a reset signal generation circuit 41. The latch-type comparator 4 shown in FIG. 10 further includes PMOS transistors PM43 to PM48, inverters IV41 and IV42, a NAND circuit NA41, and inverters IV43 and IV44. The inverters IV42 and IV43 constitute an output 4C which outputs a comparison output signal CMPOUT.

A source of the PMOS transistor PM43 is connected to the power supply voltage application end. A drain of the PMOS PM43 is connected to a source of the PMOS transistor PM44. A drain of the PMOS transistor PM44 is connected to a node to which sources of the PMOS transistors PM41 and PM42 are connected. A reset signal RST is applied to a gate of the PMOS transistor PM44.

An input end of the inverter IV41 is connected to the first end of the capacitor C41. An input end of the inverter IV42 is connected to the first end of the capacitor C42.

A source of the PMOS transistor PM45 is connected to the power supply voltage application end. A drain of the PMOS transistor PM45 is connected to a source of the PMOS transistor PM46. A drain of the PMOS transistor PM46 is connected to a first end of the capacitor C41. A source of the PMOS transistor PM47 is connected to the power supply voltage application end. A drain of the PMOS transistor PM47 is connected to a source of the PMOS transistor PM48. A drain of the PMOS transistor PM48 is connected to the first end of the capacitor C42. A reset signal RST is applied to the gates of the PMOS transistors PM45 and PM47. An output end of the inverter IV41 is connected to the gate of the PMOS transistor PM46. An output terminal of the inverter IV42A is connected to a gate of the PMOS transistor PM48.

The output end of the inverter IV42 is connected to an input end of the inverter IV43. A comparison output signal CMPOUT is outputted from the inverter IV43. A first input end of the NAND circuit NA41 is connected to the output end of the inverter IV41. The output end of the inverter IV42 is connected to a second input end of the NAND circuit NA41. The output end of the NAND circuit NA41 is connected to a gate of the PMOS transistor PM43 together with an input end of the inverter IV44. A comparison completion signal Scmp is outputted from the inverter IV44.

The switches SW41 and SW42 are turned on by the high-level reset signal RST, the capacitors C41 and C42 are discharged, and the voltage Vc1 at the first end of the capacitor C41 and the voltage Vc2 at the first end of the capacitor C42 becomes 0 V. At this time, the PMOS transistors PM44, PM45 and PM47 are turned off. Further, since the outputs of the inverters IV41 and IV42 are at a high level, the PMOS transistors PM46 and PM48 are turned off, the comparison output signal CMPOUT is reset to the low level, the comparison completion signal Scmp is at a high level, and the PMOS transistor PM43 is turned on.

Then, when the reset signal RST is switched to the low level, the switches SW41 and SW42 are turned off, and the comparison operation is started. Since the PMOS transistor PM44 is turned on, a current begins to flow through the PMOS transistors PM41 and PM42. In addition, the PMOS transistors PM45 and PM47 are turned on.

The output signal COUT1 outputted from the comparator 3 (FIG. 6) is inputted to the gate of the PMOS transistor PM41, and the output signal COUT2 outputted from the comparator 3 is inputted to the gate of the PMOS transistor PM42. For example, when COUT1>COUT2, the voltage Vc2 at the first end of the capacitor C42 is maintained at a high level, and the voltage Vc1 at the first end of the capacitor C41 is maintained at a low level. Then, the output of the inverter IV42 is at a low level, the PMOS transistor PM48 is turned on, and the power supply voltage is applied to the first end of the capacitor C42 via the PMOS transistors PM47 and PM48. As a result, by rapidly charging the capacitor C42 and rapidly changing the voltage Vc2 to the power supply voltage and the voltage Vc1 to the ground potential, it is possible to prevent the input voltages of the inverters IV41 and IV42 from becoming intermediate potentials to generate a through current. Further, the comparison output signal CMPOUT is at the high level, and the output of the NAND circuit NA41 is at a high level. As a result, the PMOS transistor PM43 is turned off, and the comparison completion signal Scmp is at a low level, which indicates the completion of comparison. When the comparison completion signal Scmp is switched to the low level, the reset signal generation circuit 41 switches the reset signal RST to the high level and performs resetting after a delay by a predetermined delay time.

In the latch type comparator 4 shown in FIG. 10, the comparison output signal CMPOUT may be reset to the low level after the comparison operation and before the next comparison operation.

### <4. Various Embodiments of Level Shifter>

Now, various embodiments of the level shifter 7 will be described. In the following description, for the sake of convenience, an alphabet is given to the reference numeral of the level shifter 7 in each of the embodiments of the present disclosure.

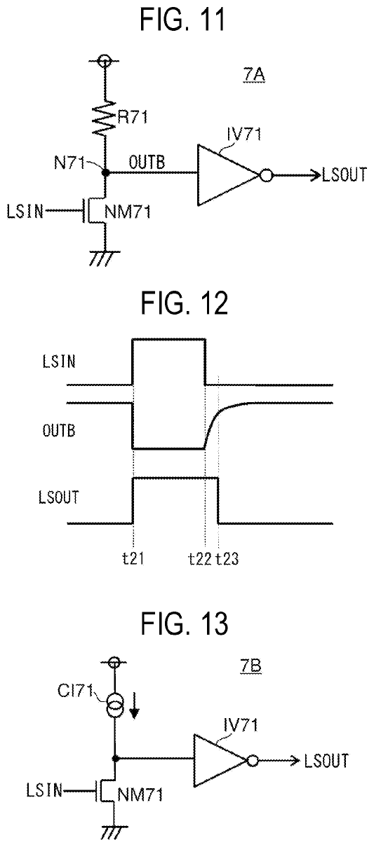

FIG. 11 is a diagram showing a structure of a level shifter 7A according to a first embodiment of the present disclosure. The level shifter 7A includes a resistor R71, an NMOS transistor NM71, and an inverter IV71.

A first end of the resistor R71 is connected to the power supply voltage application end. A second end of the resistor R71 is connected to a drain of the NMOS transistor NM71. A source of the NMOS transistor NM71 is connected to a ground potential application end. An input signal LSIN is inputted to a gate of the NMOS transistor NM71. A node N71 where the second end of the resistor R71 and the drain of the NMOS transistor NM71 are connected is connected to an input end of the inverter IV71. An output signal LSOUT is outputted from the inverter IV71.

FIG. 12 is a timing chart showing an operation example of the level shifter 7A. In FIG. 12, the input signal LSIN, a voltage OUTB of the node N71, and the output signal LSOUT are shown sequentially from the top. When the input signal LSIN rises at timing t21, the NMOS transistor NM71 is turned on, the voltage OUTB immediately falls, and the output signal LSOUT immediately rises. Then, when the input signal LSIN falls at timing t22, the NMOS transistor NM71 is turned off. However, the voltage OUTB gradually rises due to the resistor R71, and the output signal LSOUT falls at timing t23 with a delay from timing t22. According to the first embodiment of the present disclosure, it is possible to speed up the rise of the output signal LSOUT with a simple structure.

FIG. 13 is a diagram showing a structure of a level shifter 7B according to a second embodiment of the present disclosure. Compared with the first embodiment of the present disclosure, the level shifter 7B includes a constant current source CI71 instead of the resistor R71. According to the second embodiment of the present disclosure, a constant current source may be used, but an area efficiency is excellent.

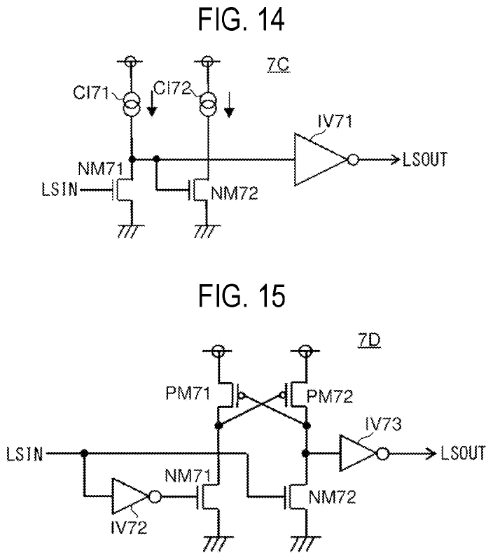

FIG. 14 is a diagram showing a structure of a level shifter 7C according to a third embodiment of the present disclosure. The level shifter 7C includes an NMOS transistor NM72 and a constant current source CI72 in addition to the structure of the second embodiment of the present disclosure. The constant current source CI72 is disposed between a power supply voltage application end and a drain of the NMOS transistor NM72. A source of the NMOS transistor NM72 is connected to a ground potential application terminal. A gate of the NMOS transistor NM72 is connected to a node where a constant current source CI71 and the NMOS transistor NM71 are connected.

When the input signal LSIN rises, a current flows through the constant current source CI71 and a current does not flow through the constant current source CI72. On the other hand, when the input signal LSIN falls, a current does not flow through the constant current source CI71 and a current flows through the constant current source CI72. As described above, the change in the current due to the change in the input signal LSIN is small, which may help noise suppression.

FIG. 15 is a diagram showing a structure of a level shifter 7D according to a fourth embodiment of the present disclosure. The level shifter 7D includes NMOS transistors NM71 and NM72, PMOS transistors PM71 and PM72, and inverters IV72 and IV73.

A source of the PMOS transistor PM71 is connected to a power supply voltage application end. A drain of the PMOS transistor PM71 is connected to a drain of the NMOS transistor NM71. A source of the NMOS transistor NM71 is connected to a ground potential application end. An input signal LSIN is inputted to an input end of the inverter IV72. An output end of the inverter IV72 is connected to a gate of the NMOS transistor NM71. A source of the PMOS transistor PM72 is connected to the power supply voltage application end. The drain of the PMOS transistor PM72 is connected to the drain of the NMOS transistor NM72. The source of the NMOS transistor NM72 is connected to the ground potential application end. A gate of the PMOS transistor PM71 is connected to the drain of the PMOS transistor PM72. A gate of the PMOS transistor PM72 is connected to the drain of the PMOS transistor PM71. A node where the drain of the PMOS transistor PM72 and the drain of the NMOS transistor NM72 are connected is connected to an input end of the inverter IV73. An output signal LSOUT is outputted from an output end of the inverter IV73.

According to the structure described above, it is possible to speed up the rise of the output signal LSOUT by lowering current capabilities of the PMOS transistors PM71 and PM72.

### <5. Sampling/Holding Switch>

As shown in FIG. 6, the DAC 1 according to the embodiments of the present disclosure includes switches S1 and S2 and switches SW1 to SW3 for sampling/holding. The switch SW3 connects the second end of the capacitor Cp and the second end of the capacitor Cn.

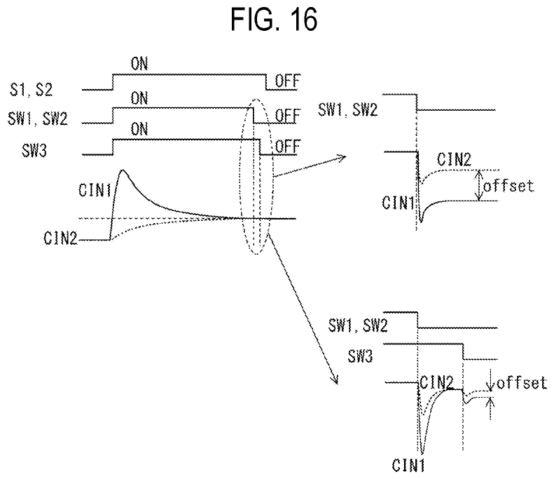

FIG. 16 is a timing chart showing an example of the operation during sampling/holding. In FIG. 16, the on/off states of the switches S1 and S2, the on/off states of the switches SW1 and SW2, the on/off state of the switch SW3, and the input signals CIN1 and CIN2 inputted to the comparator 3 are shown sequentially from the top.

When the switches S1 and S2 and the switches SW1 to SW3 are turned on at the same time, sampling/holding is started, and the input signals CIN1 and CIN2 rise from 0 V. Then, the switches SW1 and SW2, the switch SW3, and the switches S1 and S2 are turned off in this order.

The upper right side of FIG. 16 is an enlarged view when the switches SW1 and SW2 are switched from an on state to an off state in the case where the switch SW3 is not provided. In a case where sizes of the switches SW1 and SW2 are small (that is, an on-resistance is large), the capacitors Cp and Cn may not be charged within a specified time. However, in a case where the sizes of the switches SW1 and SW2 are large, an offset between the input signals CIN1 and CIN2 may be large after the switches SW1 and SW2 are switched to the off state under an influence of charge injection of the switches SW1 and SW2, as shown in the upper right side of

Therefore, in the embodiments of the present disclosure, the switch SW3, which is smaller in size than the switches SW1 and SW2, is provided. Thus, as shown in the lower right side of FIG. 16, the switches SW1 and SW2 are first turned off to wait until a difference between the input signals CIN1 and CIN2 becomes smaller. Then, the switch SW3 is turned off to make the offset small.

### <6. Others>

Various technical features of the present disclosure may be modified in various ways in addition to the above-described embodiments, without departing from the gist of the technical features of the present disclosure. That is, the above-described embodiments of the present disclosure should be considered as examples and not restrictive in all respects. The technical scope of the present disclosure is not limited to the above-described embodiments of the present disclosure, and encompasses all changes within the meaning and range equivalent to the claims.

### <7. Supplementary Note>

As described above, for example, an AD converter (10) according to the present disclosure comprises:
a DA converter (1);
a comparator (4) configured to be capable of resetting a comparison output signal (CMPOUT) to a first level after a comparison operation is performed based on an output of the DA converter and before a next comparison operation is performed;
a level shifter (7) configured to be capable of level-shifting and outputting the comparison output signal such that a change from the first level to a second level is faster than a change from the second level to the first level;
a register (6) configured to be capable of obtaining the output of the level shifter; and
a logic circuit (2) configured to be capable of controlling the DA converter (a first feature, FIG. 6).

In the first feature, the level shifter (7C) may include:
a first NMOS transistor (NM71) including a gate to which an input signal (LSIN) is capable of being inputted and a source which is capable of being connected to a ground potential application end;
a first constant current source (CI71) disposed between a first power supply voltage application end and a drain of the first NMOS transistor;
a second NMOS transistor (NM72) including a gate connected to a node where the first NMOS transistor and the first constant current source are connected, and a source which is capable of being connected to the ground potential application end;
a second constant current source (CI72) disposed between a second power supply voltage application end and a drain of the second NMOS transistor; and
a first inverter (IV71) including an input end connected to the node (second feature, FIG. 14).

In the first or second feature, the comparator (4) may include:
a first capacitor (C41);
a second capacitor (C42);
a charger (4A) configured to charge the first capacitor and the second capacitor according to a magnitude relationship between two input signals (COUT1 and COUT2);
a holder (4B) configured to hold voltage levels of the first capacitor and the second capacitor;
an output (4C) configured to output the comparison output signal based on at least one selected from the group of the voltage level of the first capacitor and the voltage level of the second capacitor; and
a reset signal generation circuit (41) configured to generate a reset signal (RST) that resets the comparison output signal while discharging the first capacitor and the second capacitor (a third feature, FIG. 9).

In the third feature, the comparator (4) may further include a signal generator (O42) configured to generate a comparison completion signal Scmp based on the voltage levels of the first capacitor (C41) and the second capacitor (C42), and the reset signal generation circuit (41) may perform resetting by the reset signal (RST) when a predetermined delay time has elapsed after the comparison completion signal indicates the completion of comparison (a fourth feature, FIG. 9).

In the third or fourth feature, the output (4C) may include a flip-flop (RS4) to which a signal based on the voltage level of the first capacitor, the voltage level of the second capacitor, and the reset signal is inputted (a fifth feature, FIG. 9).

In the third or fourth feature, the output (4C) may include an inverter (IV42 or IV43) configured to invert the voltage level of the second capacitor at least one time (a sixth feature, FIG. 10).

In any one of the first to sixth features, the logic circuit (2) may include: a detection circuit (21) configured to detect a period from when an output of a first clock signal (CK[n]) is switched to when an output of a second clock signal (CK[n+1]) is switched; the register (6) as a D flip-flop including a D input end to which the output of the level shifter (7) is inputted and a clock input end to which the second clock signal is inputted; and a control circuit (22) configured to control the DA converter (1) based on the output of the detection circuit and the output of the D flip-flop (a seventh feature, FIG. 7).

In the seventh feature, the detection circuit (21) may be a NAND circuit including an input end to which the first clock signal (CK[n]) is inputted and an inverting input end to which the second clock signal (CK[n+1]) is inputted; and the control circuit (22) may include an input end to which the output of the detection circuit is inputted and an inverting input end to which the output of the D flip-flop (6) is inputted (an eighth feature, FIG. 7).

In any one of the first to eighth features, the DA converter (1) may include: a first switch (S1); a second switch (S2); a first DAC capacitor (Cp) including a first end to which a first analog input signal (AINP) is capable of being applied via the first switch; a second DAC capacitor (Cn) including a first end to which a second analog input signal is capable of being applied via the second switch; a third switch (SW1) connected between a fixed voltage (Vs) application end and a second end of the first DAC capacitor; a fourth switch (SW2) connected between the fixed voltage application end and a second end of the second DAC capacitor; and a fifth switch (SW3) connected between the second end of the first DAC capacitor and the second end of the second DAC capacitor and being smaller in size than the third switch and the fourth switch (a ninth feature, FIG. 6).

The present disclosure may be used in AD converters applicable to various systems.

According to the AD converters in the embodiments of the present disclosure, it is possible to realize a high-speed operation.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. An AD converter, comprising:
a DA converter;
a comparator configured to be capable of resetting a comparison output signal to a first level after a comparison operation is performed based on an output of the DA converter and before a next comparison operation is performed;
a level shifter configured to be capable of level-shifting and outputting the comparison output signal such that a change from the first level to a second level is faster than a change from the second level to the first level;
a register configured to be capable of obtaining the output of the level shifter; and
a logic circuit configured to be capable of controlling the DA converter.

2. The AD converter of claim 1, wherein the level shifter includes:
a first NMOS transistor including a gate to which an input signal is capable of being inputted and a source which is capable of being connected to a ground potential application end;
a first constant current source disposed between a first power supply voltage application end and a drain of the first NMOS transistor;
a second NMOS transistor including a gate connected to a node where the first NMOS transistor and the first constant current source are connected, and a source which is capable of being connected to the ground potential application end;
a second constant current source disposed between a second power supply voltage application end and a drain of the second NMOS transistor; and
a first inverter including an input end connected to the node.

3. The AD converter of claim 1, wherein the comparator includes:
a first capacitor;
a second capacitor;
a charger configured to charge the first capacitor and the second capacitor according to a magnitude relationship between two input signals;
a holder configured to hold voltage levels of the first capacitor and the second capacitor;
an output configured to output the comparison output signal based on at least one selected from the group of the voltage level of the first capacitor and the voltage level of the second capacitor; and
a reset signal generation circuit configured to generate a reset signal that resets the comparison output signal while discharging the first capacitor and the second capacitor.

4. The AD converter of claim 3, wherein the comparator further includes a signal generator configured to generate a comparison completion signal based on the voltage levels of the first capacitor and the second capacitor, and
wherein the reset signal generation circuit is further configured to perform resetting by the reset signal when a predetermined delay time has elapsed after the comparison completion signal indicates completion of comparison.

5. The AD converter of claim 3, wherein the output includes a flip-flop to which a signal based on the voltage level of the first capacitor, the voltage level of the second capacitor, and the reset signal is inputted.

6. The AD converter of claim 3, wherein the output includes an inverter configured to invert the voltage level of the second capacitor at least one time.

7. The AD converter of claim 1, wherein the logic circuit includes:
a detection circuit configured to detect a period from when an output of a first clock signal is switched to when an output of a second clock signal is switched;
the register as a D flip-flop including a D input end to which the output of the level shifter is inputted and a clock input end to which the second clock signal is inputted; and
a control circuit configured to control the DA converter based on the output of the detection circuit and the output of the D flip-flop.

8. The AD converter of claim 7, wherein the detection circuit is a NAND circuit including an input end to which the first clock signal is inputted and an inverting input end to which the second clock signal is inputted; and
wherein the control circuit includes an input end to which the output of the detection circuit is inputted and an inverting input end to which the output of the D flip-flop is inputted.

9. The AD converter of claim 1, wherein the DA converter includes:
a first switch;
a second switch;
a first DAC capacitor including a first end to which a first analog input signal is capable of being applied via the first switch;
a second DAC capacitor including a first end to which a second analog input signal is capable of being applied via the second switch;
a third switch connected between a fixed voltage application end and a second end of the first DAC capacitor;
a fourth switch connected between the fixed voltage application end and a second end of the second DAC capacitor; and
a fifth switch connected between the second end of the first DAC capacitor and the second end of the second DAC capacitor and being smaller in size than the third switch and the fourth switch.
